(19) United States
(12) Patent Application Publication
(10) Pub. No.: US 2026/0227830 A1
(43) Pub. Date: Aug. 6, 2026

(54) ADJUSTABLE RISER CAGE

(71) Applicant: HEWLETT PACKARD ENTERPRISE DEVELOPMENT LP, Spring, TX (US)

(72) Inventors: Chien-Jen Chen, Taoyuan City (TW); Jui Lin Chen, Taipei City (TW)

(21) Appl. No.: 19/192,616

(22) Filed: Apr. 29, 2025

Related U.S. Application Data
(60) Provisional application No. 63/752,015, filed on Jan. 31, 2025.

(51) Int. Cl. G06F 1/18; H05K 7/14

(52) U.S. Cl. CPC G06F 1/185; H05K 7/1417

(57) ABSTRACT

A riser assembly includes a riser card removably connectable to an expansion slot of a primary system board of an information processing device. The riser card includes one or more riser-card expansion slots configured to receive an expansion card. A riser cage supports the riser card and defines a space to receive one or more expansion cards connected to the one or more riser-card expansion slots. The riser cage comprises a fixed bracket and an adjustable bracket. The fixed bracket is configured to be attached to a chassis of the information processing device, with the riser card attached to the fixed bracket. The adjustable bracket is coupled to the fixed bracket and comprises a support feature to support an expansion card installed in the riser cage. The adjustable bracket is adjustable between multiple configurations by moving the support feature relative to the fixed bracket along at least two dimensions.

### PRIORITY CLAIM

This application claims priority to U.S. Provisional Patent Application No. 63/752,015, filed Jan. 31, 2025, the contents of which are incorporated herein.

### INTRODUCTION

Computing systems generally comprise a set of core components provided as part of a system board (motherboard), such as a central processing unit (CPU) and a memory, as well as various peripheral components, coupled thereto. Peripheral components may allow the computing system to be enhanced and expanded beyond the core components present on the system board.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including an adjustable riser cage.

FIG. 2 is a front perspective view of an adjustable riser cage.

FIG. 3 is a side perspective view of an adjustable riser cage.

FIG. 4 is another front perspective view of an adjustable riser cage.

FIG. 5 is a front and bottom perspective view of an adjustable riser cage.

FIG. 6 is a side elevation view of an adjustable riser cage.

FIG. 7 is a side perspective view of an adjustable riser cage.

FIG. 8 is another side perspective view of an adjustable riser cage.

FIG. 9 is a perspective view of an adjustable riser cage with an adjustable bracket in a first configuration.

FIG. 10 is a perspective view of an adjustable riser cage with an adjustable bracket in a second configuration.

FIG. 11 is a side perspective view of an adjustable riser cage with an adjustable bracket in a third configuration.

FIG. 12 is a method for installing an expansion card in an adjustable riser cage.

### DETAILED DESCRIPTION

In some computing systems, peripheral components may be coupled to a system board. Some peripheral components may take the form of an expansion card configured to add functionality to the computing system. Examples of expansion cards include graphics processing unit (GPU) cards, network interface cards (NICs), etc. Expansion cards are generally electrically connected to the system board via a connector mounted to the face of the system board, which is often referred to as an expansion slot. In some systems, it is possible for an expansion card to be mated directly with the expansion slot, which usually requires the expansion card to be oriented perpendicular to the system board.

However, in some systems, the spatial configuration of the system does not allow for an expansion card to be positioned perpendicular to the system board, and therefore the expansion card cannot be mated directly to the expansion slot. In such cases, the expansion cards may be installed within the computer system using a riser card. As used herein, a riser card refers to a printed circuit board that acts as an intermediary between an expansion card and a system board, with the riser card electrically connecting these together. Furthermore, the riser card is usually configured to allow the expansion card to be positioned parallel to the system board. In addition, in some cases, multiple expansion cards can be coupled to one riser card, thus allowing for additional expansion cards to be added to the system using only one expansion slot of the system board. More particularly, a riser card may be coupled to a system board by connecting an edge connector of the riser card to a corresponding expansion slot on the system board such that the riser card extends perpendicular to the system board. The riser card may include at least one expansion slot configured to receive an edge connector of an expansion card and more particularly, may include at least one expansion slot oriented parallel to the system board (the expansion slot(s) of the riser card may be similar in form factor to the expansion slot of the system board). When an expansion card is installed within an expansion slot of the riser card, the expansion card is electrically coupled to the system board such that the functionality associated with the expansion card is enabled.

Expansion cards may come in a variety of form factors, or shapes and sizes. In some cases, these form factors may be standardized by an industry standard or specification, such as Peripheral Component Interconnect Express (PCIe) or others. In some cases, a given specification may provide for multiple different form factors which are all part of the same general family. For example, some expansion cards, including a PCIe card, may come in various form factors which vary in their lengths and heights, such as: a full-length/full-height form factor, a half-length/full-height form factor, a half-length/half-height form factor (also called “low profile” or “slim”), etc.

When using a riser card for installing an expansion card within a computing system, the riser card and expansion card are physically supported by a riser cage (also called a card holder). The riser card is attached to the riser cage in a position and orientation that will allow it to mate with the expansion slot on the system board. This riser cage also includes a space arranged to receive the expansion card in a position and orientation that allows the expansion card to mate with a slot on the riser card. Some riser cages also include attachment and/or support features which engage with the expansion card to physically support and secure the expansion card within the riser cage and maintain the integrity of the electrical connections between the various boards. However, because expansion cards come in a variety of form factors, a single riser cage may be incapable of securely receiving and holding multiple sizes of expansion cards. Thus, an information processing system manufacturer may need to design, manufacture, and stock multiple different types of riser cages to accommodate these different form factors. Furthermore, in situations where an existing system is being repaired or upgraded by replacement of an original expansion card having one form factor with a new expansion card having a different form factor, both the riser cage and the expansion card may need to be swapped for new versions, which can make the repair or upgrade more costly and more complicated. In addition, manufacturing and maintaining multiple types of riser cages involve increased development costs, increased manufacturing costs, and increases in storage and tracking requirements, as any riser cages not currently installed within the system need to be stored for potential future use.

Moreover, as expansion cards continue to develop, additional challenges arise, particularly with respect to supporting the expansion cards. For example, often the expansion cards are physically supported at: (1) the edge connector of the expansion card (e.g., by the mating between the edge connector and the slot on the riser card), and (2) a rear end of the expansion card, which may be attached to a rear bracket of the riser cage. However, as the gross weight of expansion cards increases, providing support to the expansion cards at just these two locations may no longer be sufficient to hold an expansion card, particularly during transportation. In particular, a distal-front corner of the expansion card, meaning a corner where a front end of the expansion card meets a distal side of the expansion card (the side opposite from a proximal side carrying the edge connector), is usually not supported and thus may droop gradually over time under the weight of the expansion card. Or this unsupported corner may move more abruptly if subjected to shock or vibration. Whether gradual or abrupt, the movement of the unsupported front end can create strain (bending and/or torsion) on the PCB edge connector and/or slot of the riser card, which can result in either or both being damaged, potentially rendering the card unusable.

To address these and other issues, examples disclosed herein relate to an adjustable riser cage for holding one or more expansion cards. The riser cage includes a front support configured to support a distal-front corner of an expansion card, with the front support being adjustable in position along at least two dimensions so as to be able to engage with the distal-front corner of multiple different expansion cards having varying lengths and varying heights. This can allow a single riser cage design to be used with multiple different form factors of expansion cards, thus reducing development, manufacturing, and logistical costs, while also making field repair or upgrade easier. In addition, the support provided to the distal-front corner by the riser cage can avoid the potential damage described above.

An adjustable bracket is coupled to the riser cage. The adjustable bracket may include at least one adjustable side portion and an adjustable front portion, and in some examples, may include two adjustable side portions. Each adjustable side portion may be adjustable in a front to rear direction, corresponding to adjustment along a y-axis. More particularly, a first adjustable side portion may move along the fixed side portion of the riser cage, with such movement being along the y-axis. A second adjustable side portion may be separated from the first adjustable side portion such that the second adjustable side portion moves parallel to the fixed side portion of the riser cage, again along the y-axis. In this manner, the first and second adjustable side portions may be movable between multiple length configurations. More particularly, the first and second adjustable side portions may be movable between a first configuration, which may correspond to a full-length expansion card, and a second configuration, which may correspond to a half-length expansion card, allowing either expansion cards of both lengths to be received within the riser cage. The adjustable side portions may engage with the parallel slots on the fixed top portion of the riser cage, with each slot of the parallel slots holding one of the adjustable side portions in a desired y-position. In addition, fasteners such as screws may be used to hold each side portion of the adjustable side portion in a desired y-position. In some examples, the riser cage includes a fixed top portion coupled to a riser card, with the riser card including at least one expansion card slot. The fixed top portion includes a pair of parallel openings extending inward from an edge of the fixed top portion. In addition, the fixed top portion may include a plurality of attachment features distributed along a front to rear direction and designed to engage with an adjustable bracket. A fixed side portion extends perpendicularly down from the top bracket parallel to the riser card such that, as an expansion card is inserted into the riser card, the expansion card moves perpendicular to slots in the riser card and thus perpendicular to side wall.

The adjustable front portion may be coupled to the pair of adjustable side portions such that, as the pair of adjustable side walls are moved in a y-direction, the adjustable front portion also moves along the y-axis. In the first configuration, the adjustable front portion may extend away from a front edge of the fixed top portion of the riser cage, thus allowing a full-length expansion card to be received within the riser card. By contrast, in the second configuration, the front edge of the fixed top portion of the riser cage overhangs the adjustable front portion. In this manner, the length of the riser cage may be adjusted to accommodate both a full-length and a half-length expansion card within the same riser cage.

In addition to being adjustable in a front to rear direction, or along a y-axis, the second adjustable side portion may also be adjustable in a second direction perpendicular to the front to rear direction. This second direction may correspond to an x-direction, with movement along an x-axis. More particularly, the second adjustable side portion may be movable between a first and second position to accommodate a full height expansion card as well as a half-height, or low profile, expansion card. In the first position, the second adjustable side portion may accommodate a full height expansion card, while in the second position, the second adjustable side portion may accommodate a half-height expansion card. The second adjustable side portion may engage with the adjustable front portion at a longitudinal slot disposed at least partially along the adjustable front portion such that the second adjustable side portion may slide with respect to the adjustable front portion at the longitudinal slot to increase or decrease the relative height between the first adjustable side portion and the second adjustable side portion. More particularly, the second adjustable side portion may be slid perpendicular to the first adjustable side portion and parallel to the adjustable front portion along the longitudinal slot. The second adjustable side wall may be held in place by fasteners inserted into apertures in the second adjustable side wall through the longitudinal slot of the adjustable rear wall, or by other attachment features.

As a result of the adjustability in both the x-and y-directions, a riser cage may be adjusted to hold expansion cards having a variety of form factors. For example, when the pair of adjustable side portions and the adjustable front portion are in a first position with respect to the y-axis and the second adjustable side portion is in a first position with respect to the x-axis, the riser cage may accommodate full-length/full-height expansion cards. When the pair of adjustable side portions and the adjustable front portion are in a second position with respect to the y-axis and the second adjustable side portion is in the first position with respect to the x-axis, the riser cage may accommodate full-height/half-length expansion cards. Further, when the pair of adjustable side portions and the adjustable front portion are in the second position with respect to the y-axis and the second adjustable side portion is in a second position with respect to the x-axis, the riser cage may accommodate half-height/half-length expansion cards. As a result, instead of having to swap out a riser cage when an expansion card having a different form factor is used, a single riser cage may be adjusted based on the particular form factor of the expansion card being used within the system.

In addition, a latching mechanism may be disposed perpendicular to the fixed side portion to engage with the expansion card when the expansion card is installed within the riser cage. The latching mechanism may include a protrusion feature to engage with the expansion card and a handle by which a user can selectively move the latching mechanism to allow insertion or removal of an expansion card.

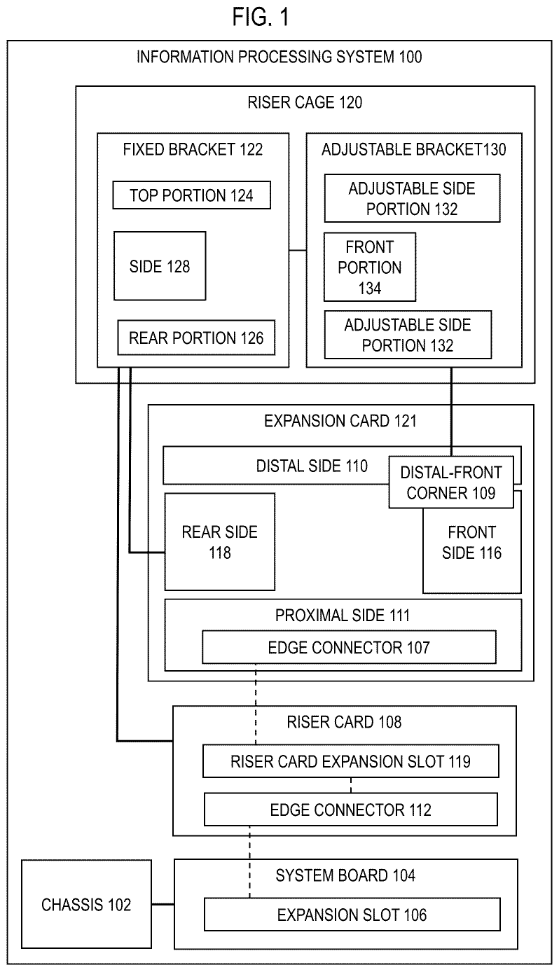

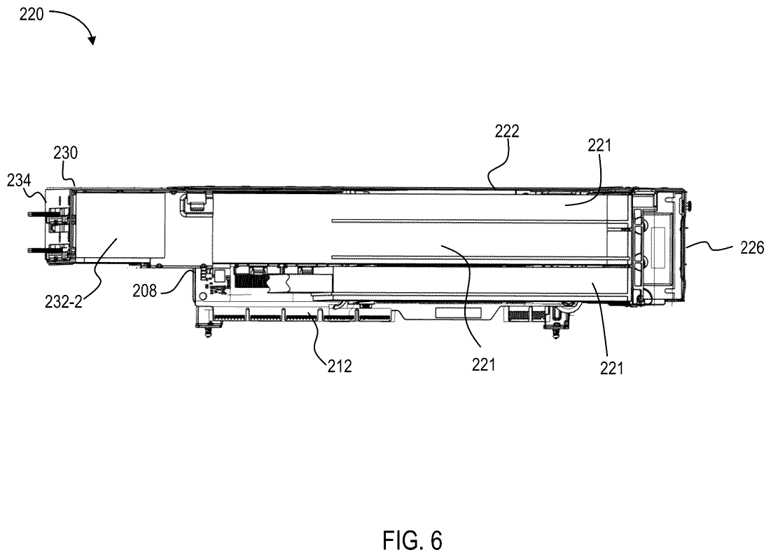

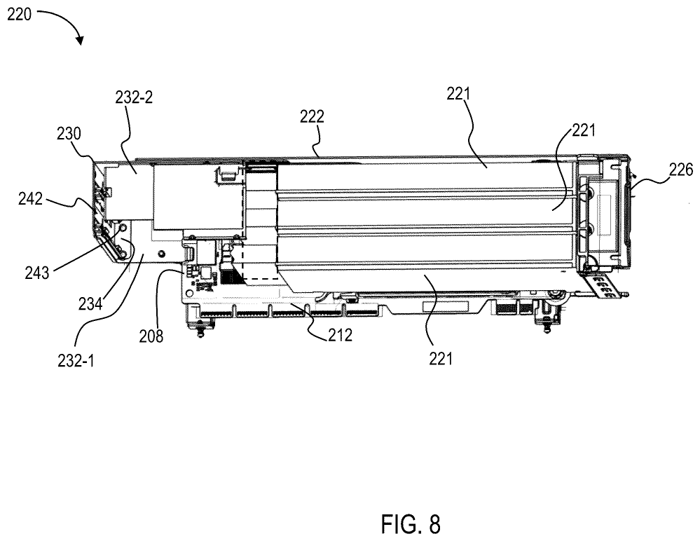

These and other examples will be described in greater detail below in relation to FIGS. 1-11.

FIG. 1 illustrates an example information processing system 100. FIG. 1 is schematic in nature, and it should be understood that FIG. 1 is not intended to illustrate specific shapes, dimensions, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components, while electrical connections between components are indicated conceptually by dashed lines extending between the components.

Information processing system includes a chassis 102 which physically supports, and in some cases encloses or houses, the other components of the system 100. The chassis 102 may include structural components such as a front panel, a rear panel, and side panels which together define the chassis 102. Chassis 102 may further include other structural members (not illustrated) such as a base, a cover, etc.

A system board 104 may be supported by the chassis 102. The system board 104 may be a motherboard that includes a processor, a memory, and other core components (not illustrated), but examples are not so limited and any system board may be used. The system board 104 may include an expansion slot 106. An expansion slot refers to a connector on a system board configured to receive an expansion card or riser card.

More particularly, expansion slot 106 may be configured to receive a riser card such as riser card 108 by receiving and engaging an edge connector 112 on a proximal side of the riser card 108. Upon engaging the edge connector 112 of the riser card 108, riser card 108 is electrically connected to the system board 104.

In an engaged state of the riser card 108 with the expansion slot 106, a proximal side of the riser card may be adjacent to the system board 104 and a distal side of the riser card extends away from the system board 104, such that riser card 108 is positioned perpendicular to the system board 104. A front side of the riser card 108 may face a front of chassis 102 while a rear side of the riser card 108 may face a rear of chassis 102, with the rear of the chassis 102 referring to the portion of the chassis facing into the system 100 and the front of the chassis 102 being disposed opposite the rear of the chassis 102.

Riser card 108 may further include at least one riser card expansion slot 119. Although only one riser card expansion slot 119 is shown in FIG. 1, examples are not so limited and other numbers of riser card expansion slots 119 may be included on riser card 108. Riser card expansion slot 119 may be orientated parallel to the system board 104. Riser card expansion slot 119 may be configured engage with an expansion card 121 at an edge connector of expansion card 121. Thus, an additional expansion card 121 may be installed within system 100, with riser card 108 acting as an intermediary between the system board 104 and expansion card 121. More particularly, when expansion card 121 is installed within the riser card expansion slot 119, expansion card 121 is electrically coupled to the system board 104, allowing the functionality of the expansion card 121 to be enabled. Because riser card expansion slot 119 is oriented parallel to the system board 104, expansion card 121, when in an installed state, also extends parallel to system board 104.

System 100 may further include a riser cage 120. The riser cage 120 may be coupled to riser card 108 such that riser card 108 is supported by the riser cage 120. Riser cage 120 may include a fixed bracket 122 and an adjustable bracket 130 coupled to one another. Fixed bracket 122 may include a top portion 124, a rear portion 126, and at least one side portion 128. Each of top portion 124, rear portion 126, and side portion 128 may be mutually perpendicular to one another. Rear portion 126, when installed in system 100, may be adjacent to a rear wall of chassis 102. In some examples, rear portion 126 of riser cage 120 may form a rear wall of the chassis 102 when the riser cage 120 is installed within system 100.

Adjustable backet 130 may include a pair of adjustable side portions 132 and an adjustable front portion 134 disposed between adjustable side portion 132. Adjustable side portions 132 and adjustable front portion 134 may be adjustable with respect to fixed bracket 120. More particularly, adjustable side portions 132 may be adjustable in a first, front-to-rear direction with respect to fixed bracket 122, allowing adjustable side portions 132 to be moved towards and away from the rear portion 126 of the fixed bracket 122, parallel to side portion 128, thus allowing the adjustable side portions 132 to be moved between multiple configurations. The top portion 124 of fixed bracket 122 may include parallel slots configured to engage with the adjustable side portions 134 as adjustable side portions 134 move with respect to fixed bracket 122. In some examples, when adjustable side portions 134 are in a desired position, adjustable side portions 134 may be fixed in the front-to-rear, or y-position, at attachment features disposed on the top portion 124 of fixed bracket 122 and corresponding attachment features on adjustable side portions 132. In some examples, the attachment may include the use of fasteners, although examples are not so limited.

In addition to the adjustable side portions 132 being adjustable in a front-to-rear, or y-direction, front portion 134 may also be adjustable in the same front-to-rear or y-direction. As adjustable side portions 132 are moved in the y-direction, front portion 134 may also move along the y-direction, thus moving the entire adjustable side bracket 130 between multiple configurations in the y-direction. As a result, adjustable side bracket 130 may be moved between a variety of lengths.

At least one of the adjustable side portions 132 may also be adjustable in a second direction perpendicular to the first direction. The second direction may be an x-direction, such that the adjustable side portion 132 is adjustable along the x-axis between multiple x-configurations. Adjustable side portion 132 may be adjustable with respect to the adjustable front portion 134 and, more particularly, may engage with a longitudinal slot formed in the adjustable front portion 134 such that adjustable side portion 132 may be moved parallel to the adjustable front portion 134 along the longitudinal slot. Thus, adjustable side portion 132 may be moved perpendicular to the other adjustable side portion 132, allowing a relative height between the adjustable side portions 132 to be selectively increased or decreased.

When expansion card 121 is installed in riser card expansion slot 119, riser cage 120 may support expansion card 121. More particularly, expansion card 121 may be installed in the riser card expansion slot 119 at an edge connector 107 of the expansion card 121. Edge connector 107 may be disposed on a proximal side 111 of the expansion card 121. A distal side 110 may extend opposite the proximal side 111, away from the riser card expansion slot 119. The expansion card 121 may further have a front side 116, oriented to be parallel to a front of the chassis 102, and a rear side 118 opposite the front side 116, oriented to be parallel to a rear of the chassis 102.

In some examples, the riser cage 120 may support expansion card 121 at a distal-front corner 109 of the expansion card 121, and more particularly, the adjustable front portion 130 may engage with the expansion card 121 to provide support for expansion card 121 at the distal-front corner 109. The distal-front corner 109 refers to the portion of the expansion card 121 that is at, or adjacent to, the location where the distal side 110 meets the front side 116. In addition, riser cage 120 may include a latching mechanism that may selectively engage with the expansion card 121 when the expansion card 121 is coupled to the riser card expansion slot 119, thus providing an additional point of support for expansion card 121.

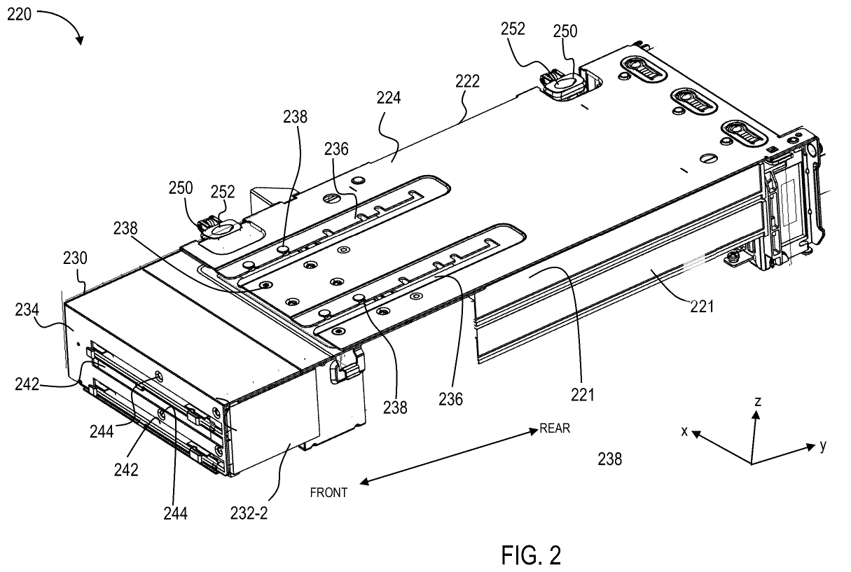

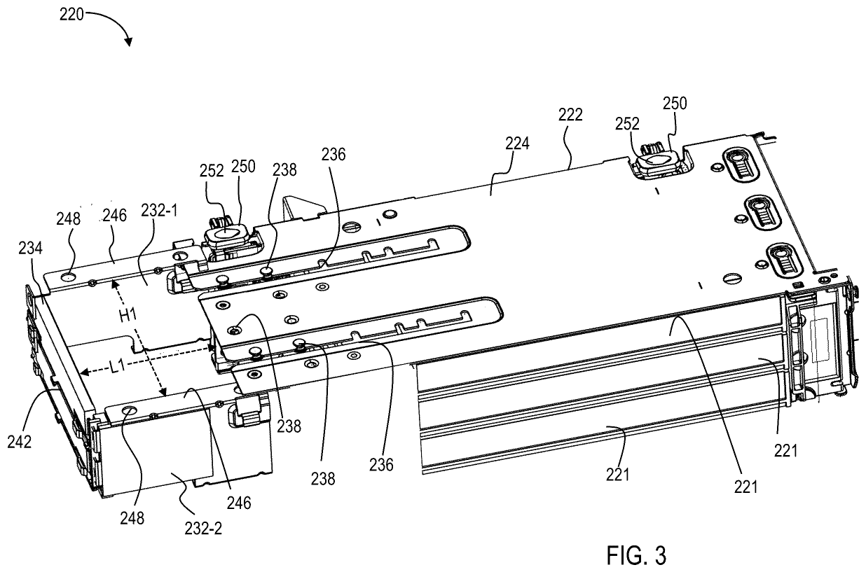

Turning to FIGS. 2-11, an example riser cage 220 is shown. Riser cage 220 may be one implementation example of riser cage 120 shown in and described with respect to FIG. 1 and may be used in a system such as system 100, described with respect to FIG. 1. Riser cage 220 thus comprises components which correspond to (i.e., are implementation examples of) components of the riser cage 120, and the correspondence between such components is indicated herein by the components having reference numbers with the same last two digits, such as 126 and 226. Aspects of the riser cage 120 and its components described above may also be applicable to the riser cage 220 and its corresponding components, but the riser cage 120 and its components are not limited to the riser cage 220 and its components, which are just one example of how the riser cage 120 may be implemented. In some instances, aspects of the riser cage 120 already described above, which are also applicable to the riser cage 220, are not described below to avoid duplicative description. In addition, dash-line rectangles, such as those in FIGS. 3 and 10-11, enclose exclusion areas present in the drawings, and are not to be construed as part of the figures.

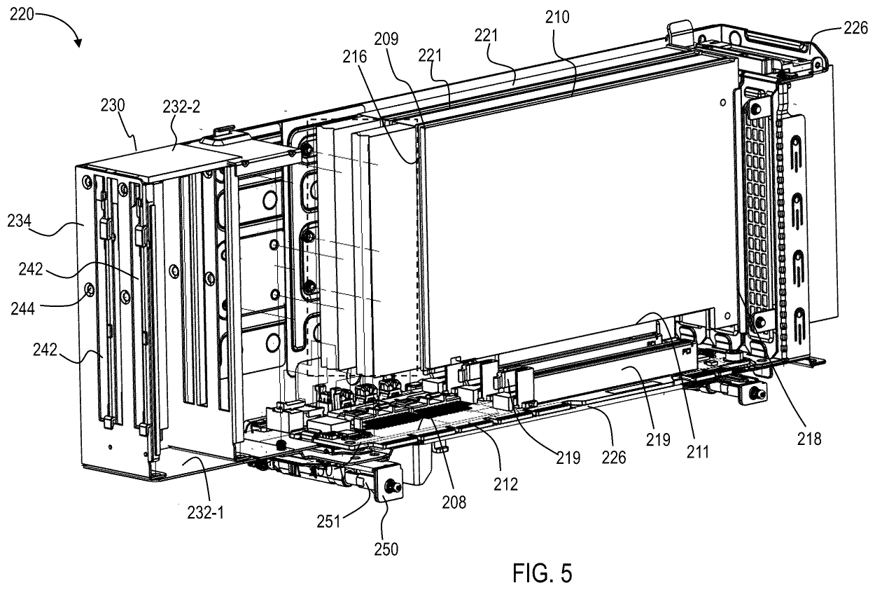

Riser cage 220 may be coupled to a riser card 208, such that at least a portion of riser card 208 may extend from riser card 208. More particularly, as shown in, e.g., FIGS. 5-8, riser card 208 may have an edge connector 212 on a proximal side of the riser card 208, with the edge connector 212 extending past riser cage 220, such that edge connector 212 is free to couple with a system board such as system board 104, shown in FIG. 1.

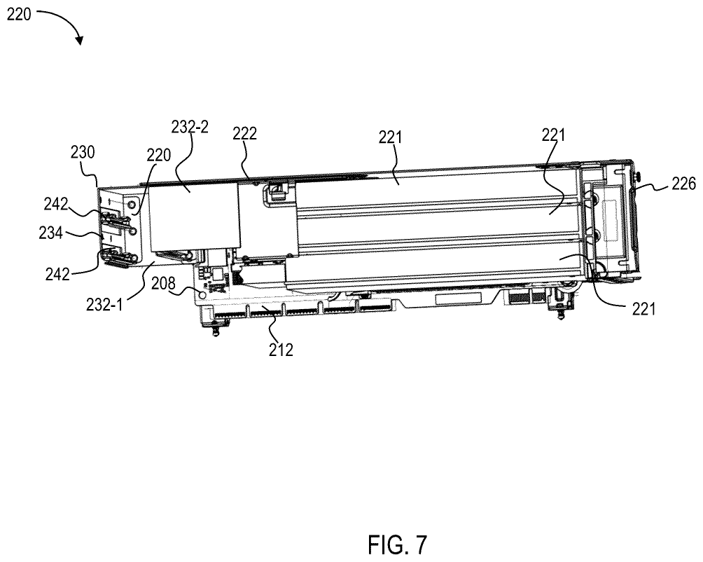

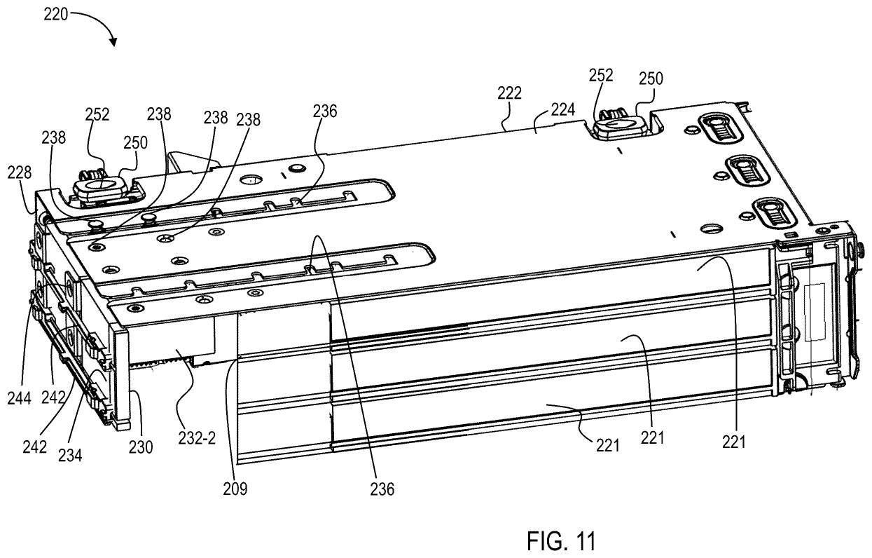

Riser card 208 includes a plurality of riser card expansion slots 219. FIG. 5 shows three riser card expansion slots 219 formed on riser card 208, with two of the riser card expansion slots 219 having an expansion card 221 coupled thereto. However, examples are not so limited, and other numbers of riser card expansion slots 219 may be included on riser card 208. In addition, while FIGS. 5 and 11 show examples of riser cage 220 with two expansion cards 221 installed, it is to be understood that more or fewer expansion cards 221 may be installed, as is shown in FIGS. 2-4 and 5-10. Expansion card slots 219 extend perpendicularly from a face of riser card 208, such that an expansion card 221 installed within a riser card expansion slot 219 is oriented perpendicular to the riser card 208. More particularly, as shown in FIG. 5, expansion card 221 is installed via connection between an edge connector (not shown in FIG. 5) and a corresponding riser card expansion slot 219, such that a proximal side 211 of the expansion card 221 is adjacent the riser card expansion slot. A distal side 210 may be opposite proximal side 211. Expansion card 221 may further have a rear side 218, located adjacent to fixed rear portion 226, and a front side 216, located opposite the rear side 218. The distal side 210 and the front side 216 may meet at a distal front corner 209. Distal front corner 209 may be supported by adjustable side bracket 232-2, as shown in FIGS. 7 and 11.

Riser cage 220 includes a fixed bracket 222 comprising a top portion 224, a fixed rear portion 226, and at least one fixed side portion 228. As shown in FIG. 5, fixed rear portion 226 may be at least partially grated such that, when riser cage 220 is installed within a chassis, such as chassis 102, fixed rear portion 226 may allow airflow through the grate and over the various components of riser cage 220. In some examples, the fixed rear portion 226 may form a rear chassis wall when riser cage 220 is installed within a system.

Fixed top portion 224 is perpendicular to fixed rear portion 226 and fixed side portion 228 and extends forward from fixed rear portion 226. Fixed top portion 224 includes a pair of openings 236 extending at least partially along the fixed top portion 224 in the front-rear direction. The pair of openings may engage with side walls 232-1, 232-2 (collectively, side walls 232) of an adjustable bracket 230.

Fixed top portion 224 may further include a plurality of attachment points 238 disposed along a front-rear direction of the fixed top portion 224. Attachment points 238 may be configured to engage with corresponding attachment points 248 on adjustable bracket 230, as described further herein.

Fixed side wall 228 is perpendicular to both fixed top portion 224 and fixed rear portion 226. Although only one fixed side wall 228 is shown in FIGS. 2-11, examples are not so limited and riser cage 220 may have a pair of fixed side walls 228 offset from one another and separated by fixed top portion 224 and fixed rear portion 226. Fixed side wall 228 may be parallel to riser card 208 when riser cage 220 is coupled to riser card 208.

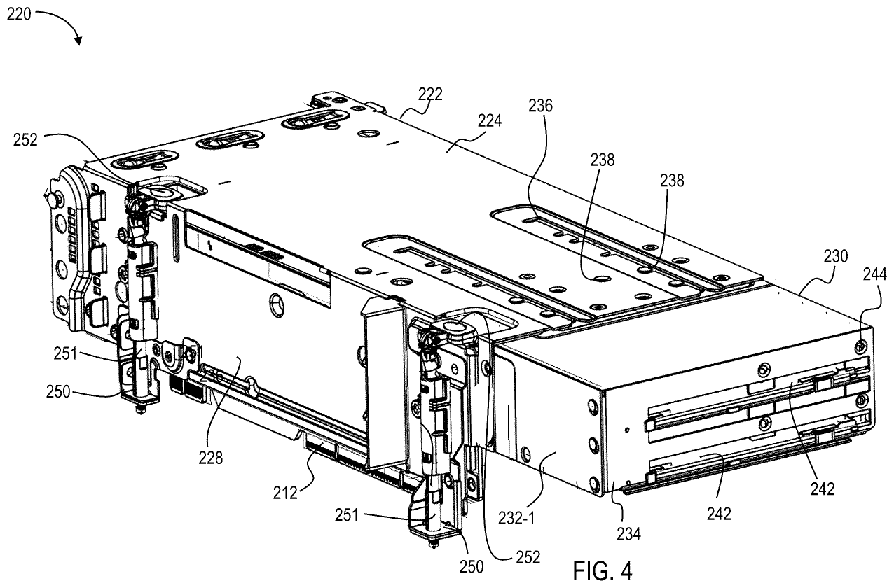

Fixed side wall 228 may include a latching mechanism 250. As shown in FIG. 4, latching mechanism 250 may be formed as part of or coupled to fixed side wall 228 such that fixed side wall 228 provides support for latching mechanism 250. Latching mechanism 250 includes a latch 251 and a handling portion 252. Handling portion 252 may be configured to be engaged by a user such that a user can selectively engage and disengage the latch 251. More particularly, latch 251 may be selectively engaged with an expansion card 221 when the expansion card 221 is installed in a riser card expansion slot 219, providing an additional point of contact and support between the riser cage 220 and the expansion card 221.

Riser cage 220 may further include an adjustable bracket 230. Adjustable bracket 230 may include a first adjustable side portion 232-1, a second adjustable side portion 232-2 (collectively adjustable side portions 232), and an adjustable front portion 234 coupled to adjustable side portions 232 such that first adjustable side portion 232-1 is offset from second adjustable side portion 232-2.

Adjustable side portions 232 may be engaged with openings 236 of fixed top portion 224 to allow adjustable side portions 232 and adjustable front portion 234 to move in a first direction with respect to the fixed bracket 222. More particularly, adjustable side portions 232 may be moved along the openings 236 in a forward-rear, or y-direction, and may be movable between a plurality of positions. Because adjustable front portion 234 is coupled to adjustable side portion 232, movement of the adjustable side portions 232 in the y-direction allows adjustable front portion 234 to also move with respect to the fixed bracket 222.

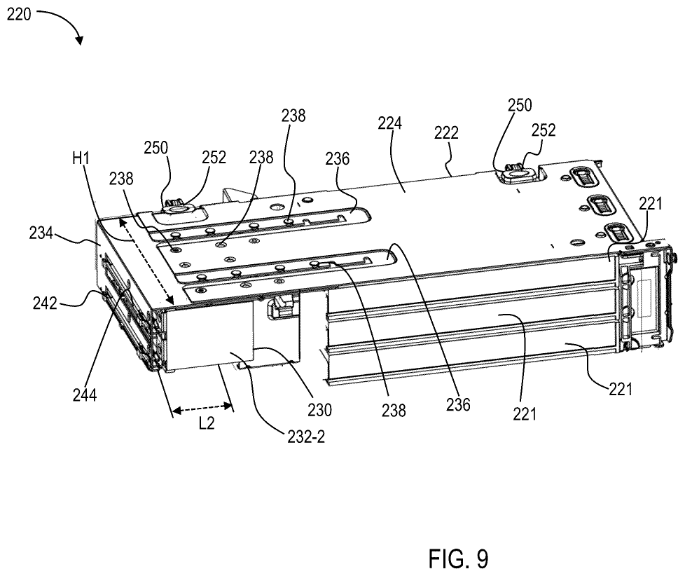

In some examples, adjustable bracket 230 may be movable in the y-direction between a first position and a second position. The first position may correspond to an extended position with respect to the fixed bracket 222, such that the adjustable bracket 230 is at a first length L1, shown in, e.g., FIG. 3. The first height L1 may correspond to the length of a full-length expansion card, such that the adjustable bracket 230 being in a first y-position may support a full-length expansion card. By contrast, the second position may correspond to a retracted position with respect to the fixed bracket 222, such that the adjustable bracket 230 is at a second length L2, shown in, e.g., FIGS. 9 and 11. The second length L2 may correspond to the length of a half-length expansion card, such that when adjustable bracket 230 is in the second y-position, the adjustable bracket 230 is configured to support a half-length expansion card.

Adjustable bracket 230 may be fixed in the y-direction by engagement between the adjustable side walls 232 and the attachment features 238 of fixed top portion 224. More particularly, each adjustable side wall 232 may include a top bracket 246 having at least one corresponding attachment feature 248 disposed within the bracket 246. As adjustable side walls 232 move along the openings 236 of fixed top portion 224, top bracket 246 slides along fixed top portion 224. When adjustable side walls 232 are in a desired position, e.g. in one of the first and second positions, an attachment feature 248 of the top bracket 246 may be aligned with an attachment feature 238 on the fixed top portion 224, allowing the adjustable side walls 232 to be fixed in the y-direction with respect to the fixed top portion 224 in the desired position.

In addition to being adjustable in the y-direction, second adjustable side wall 232-2 may be further adjustable in a second direction, which may correspond to an x-direction. More particularly, second adjustable side wall 232-2 may be engaged with adjustable front portion 234 at an opening 242 of adjustable front portion 234, allowing second adjustable side wall 232-2 to be moved along the opening 242 between a first position and a second position.

Adjustable front portion 234 may include a plurality of attachment features 244 disposed along the opening 242. Attachment features 244 may engage with the second adjustable side portion 232-2 to fix second adjustable side portion 232-2 with respect to the adjustable front portion 234 in the x-position.

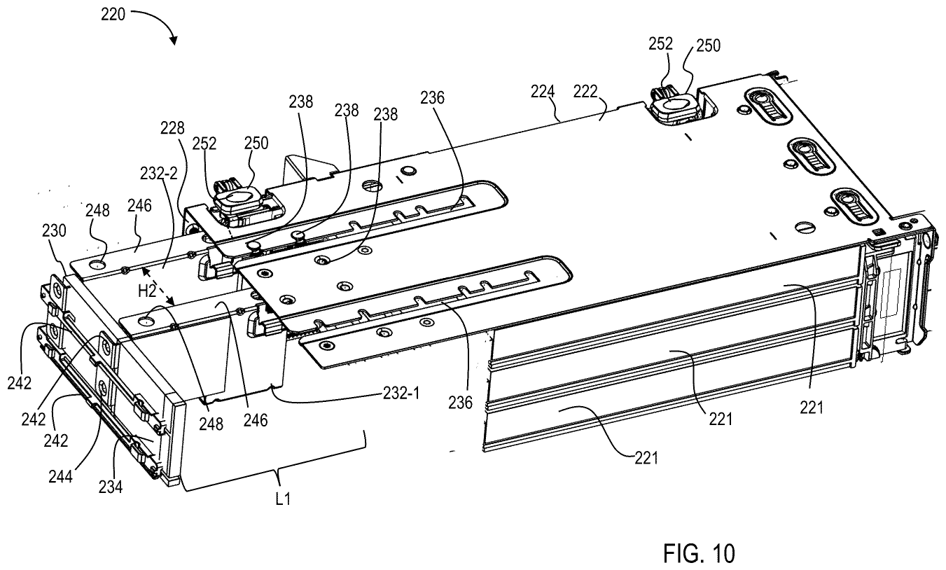

In the first position, shown in FIGS. 3 and 9, the second adjustable side wall 232-2 is separated from the first adjustable side wall 232-1 by a first height H1. The first height H1 may correspond to the height of a full-height expansion card, such that when the second adjustable side wall 232-2 is in the first position, adjustable bracket 230 is configured to support a full-height expansion card. In the second position, shown in FIGS. 10-11, the second adjustable wall 232-2 is separated from the first adjustable side wall 232-1 by a second height H2, with H2 being smaller than H1. The second height H2 may correspond to the height of a half-height expansion card, such that when the second adjustable side wall 232-2 is in the second position, adjustable bracket 230 is configured to support a half-height expansion card.

Thus, adjustable bracket 230 is configured to be movable between three configurations. In the first configuration, shown in FIG. 3, the adjustable front portion 234 and the adjustable side portions 232 are in the first position with respect to both the x-direction and the y-direction, such that the adjustable side portions 232 are separated from one another by first height H1 and adjustable front portion 234 is separated from fixed bracket 222 by first length L1. In this position, riser cage 220 is configured to receive a full-length/full-height expansion card. In the second configuration, shown in FIG. 9, the adjustable front portion 234 and the adjustable side portions 232 are in the second position with respect to the x-direction but are in the first position with respect to the y-position. In the second configuration, the adjustable side portions 232 remain separated from one another by first height H1; however, adjustable side portions 232 and adjustable front portion 234 have been moved along openings 236 of fixed top portion 224, such that adjustable front portion 234 has been moved rearward of the first position, reducing the length between the front portion 234 and the fixed bracket 222 to L2. The second configuration allows riser cage 220 to receive a half-length/full-height expansion card.

The third configuration, shown in FIGS. 10-11, allow the riser cage 220 to receive a half-length/half-height expansion card. In the third configuration, the adjustable bracket 230 is in the second x-position and the second y-position. More particularly, in the third configuration, the second adjustable side wall 232-2 is moved with respect to adjustable front wall 234 to reduce the separation between the first adjustable side wall 232-1 and the second adjustable side wall 232-2 from first height H1 to second height H2. In addition, the adjustable side walls 232 and adjustable front bracket 234 are in the second position in the y-direction.

In each of the configurations of the adjustable bracket 230, the adjustable bracket 230 and the fixed bracket 222 define a space in which an expansion card 221 can be received when expansion card 221 is connected to a riser card expansion slot 219. Moreover, in each of the configurations of the adjustable bracket 230, the second adjustable side wall 232-2 may be configured to support an expansion card 221 at a distal-front corner thereof when the expansion card 221 is in an installed state. Because adjustable bracket 230 is movable with respect to the fixed bracket 222 in multiple directions, and thus may be moved between multiple configurations, expansion cards 221 may be interchanged between various form-factors without losing support from the adjustable bracket 230 and from the adjustable side wall 232-2 in particular.

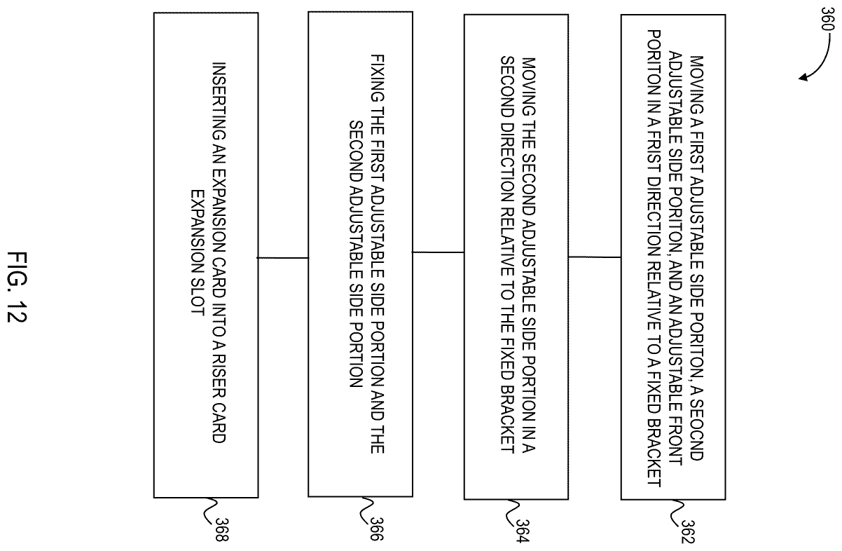

FIG. 12 is a method 360 for installing an expansion card in an adjustable riser cage. At 362, method 360 may include moving a first adjustable side portion, a second adjustable side portion, and an adjustable front portion in a first direction relative to a fixed bracket. The first and second adjustable side portions and adjustable front portion may correspond to first and second adjustable side portions 232-1, 232-2 and adjustable side portion 234, and the fixed bracket may correspond to fixed bracket 222, described with respect to FIGS. 2-11. The fixed bracket may further comprise a fixed top portion, a fixed side portion, and a fixed rear portion, which may correspond to fixed top portion 224, fixed side portion 228, and fixed rear portion 226, respectively. In some examples, moving the first and second adjustable side portions and adjustable front portion may comprise moving the first and second adjustable side portions relative to the fixed top portion of the fixed bracket, with the first and second adjustable side portions being movably engaged with the fixed top portion of the fixed bracket.

At 364, method 360 may include moving the second adjustable side portion in a second direction relative to the fixed bracket. The second direction may be perpendicular to the first direction. In some examples, moving the second adjustable side portion may comprise moving the second adjustable side portion relative to the adjustable front portion, with the second adjustable side portion being movably engaged with the adjustable front portion.

At 366, method 360 may include fixing the first adjustable side portion and the second adjustable side portion. More particularly, the first and second adjustable side portions may be fixed relative to the fixed top portion of the fixed bracket. In some examples, fixing the first and second adjustable side portions comprises engaging the first and second adjustable side portions with attachment points disposed on the fixed top portion of the fixed bracket. The attachment points may selectively engage with corresponding attachment points on the first and second adjustable side portions, allowing the first and second adjustable side portions to be fixed in a desired position when moved in the first direction.

Fixing the first and second adjustable side portions at 366 may further comprise engaging the second adjustable side portion with attachment points on the adjustable front portion. The attachment points on the adjustable front portion may be selectively engageable with corresponding attachment points on the second adjustable side portion. Thus, the second adjustable side portion may also be fixed in position when moved in the second direction.

At 368, method 360 may include inserting an expansion card into a riser card expansion slot. The expansion card, when inserted, may be bounded by the first and second adjustable side portions and the adjustable front portion, with the second adjustable side portion supporting a corner of the expansion card. In some examples, the movement of the first and second adjustable side portions and adjustable front portion in the first direction and the movement of the second adjustable side portion in the second direction may correspond to movement to adjust the first and second adjustable side portions and adjustable front portion such that the expansion card is supported in the inserted state. More particularly, the adjustments in the first and second directions may be made to correspond to a particular form factor of the expansion card to allow the expansion card to be supported in the inserted position.

Method 360 may further include engaging a latch with the expansion card upon insertion of the expansion card into the riser card expansion slot. The latch may be selectively engageable by a user to provide an additional point of contact and support for the expansion card in the installed state.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. A riser assembly, comprising:
a riser card configured to be removably connected to an expansion slot of a primary system board of an information processing device, the riser card having one or more riser-card expansion slots, each riser-card expansion slot configured to receive an edge connector of an expansion card; and
a riser cage supporting the riser card and defining a space in which to receive one or more expansion cards connected to the one or more riser-card expansion slots, the riser cage comprising:
a fixed bracket configured to be attached to a chassis of the information processing device, the riser card being attached to the fixed bracket; and
an adjustable bracket coupled to the fixed bracket, the adjustable bracket comprising a support feature arranged to support an expansion card installed in the riser cage, the adjustable bracket being adjustable between multiple configurations by moving the support feature relative to the fixed bracket along at least two dimensions to accommodate multiple expansion card form factors having varying lengths and varying heights.

2. The riser assembly of claim 1, wherein:
the fixed bracket further comprises a top portion, a rear portion, and a side portion; and
the top portion, the rear portion, and the side portion are mutually perpendicular.

3. The riser assembly of claim 1, wherein the adjustable bracket further comprises:
a first adjustable side portion disposed adjacent the side portion of the fixed bracket;
a second adjustable side portion disposed parallel to the first adjustable side portion and offset by a first distance; and
an adjustable front wall disposed between and connecting the first adjustable side portion and the second adjustable side portion.

4. The riser assembly of claim 1, wherein:
the expansion card further comprises:
a proximal side including the edge connector;
a distal side opposite the proximal side;
a rear side supported by a rear portion of the fixed bracket; and
a front side opposite the rear side, wherein a distal-front corner comprises a portion of the card adjacent an intersection of the front side and the distal side of the card; and
the support feature supports the expansion card at the distal-front corner of the expansion card.

5. The riser assembly of claim 1, wherein the multiple configurations further comprise:
a first configuration in which the support feature is positioned to support a full-length/full-height (FL/FH) expansion card;
a second configuration in which the support feature is positioned to support a half-length/full-height (HL/FH) expansion card; and
a third configuration in which the support feature is positioned to support a half-length/half-height (HL/HH) expansion card.

6. The riser assembly of claim 5, wherein:
in the first configuration, the front portion is positioned at a first position and the second side portion is positioned at a first position;
in the second configuration the front portion is positioned at a second position rearward of the first position and the second side portion is positioned at the first position; and
in the third position, the front portion is positioned at the second position and the second side portion is positioned at a second position.

7. The riser assembly of claim 5, wherein:
the top wall includes a plurality of attachment points distributed along a front-rear direction; and
in the first configuration the adjustable bracket is attached to a first set of the attachment points and in the second and third configurations the adjustable bracket is attached to a second set of the attachment points.

8. The riser assembly of claim 5:
the adjustable front wall includes a plurality of attachment points distributed along a length portion of the adjustable front wall; and
in the first and second configurations, the second side portion is attached to a first set of the attachment points and in the third configuration the second side portion is attached to a second set of the attachment points.

9. The riser assembly of claim 1, further comprising a latching mechanism, the latching mechanism further comprising:
a latch to engage with an expansion card in a state of the expansion card installed within a slot of the riser card; and
a handling portion configured to be engaged by a user to selectively disengage the latch from the expansion card.

10. A system, comprising:
a chassis;
a system board supported by the chassis, the system board including an expansion slot;
a riser card coupled to the system board at the expansion slot and including a riser-card expansion slot to receive an expansion card; and
a riser cage coupled to and supporting the riser card, the riser cage comprising:
a fixed bracket attached to the chassis and comprising a fixed top portion disposed perpendicular to the riser card, a fixed side portion extending parallel to the riser card, and a fixed rear portion extending perpendicular to the fixed top portion and the fixed side portion; and
an adjustable bracket coupled to the fixed bracket, the adjustable bracket further comprising:
an adjustable side wall movable relative to the fixed bracket in a first direction and a second direction, the second direction perpendicular to the first direction
an adjustable front portion movable in the first direction and connected perpendicularly to the adjustable side wall,
wherein the fixed bracket and the adjustable bracket define a space to receive an expansion card connected to the expansion slot.

11. The system of claim 10, wherein the adjustable bracket is adjustable between multiple configurations by moving the adjustable bracket relative to the fixed bracket along at least two dimensions.

12. The system of claim 10, wherein:
the adjustable side wall is a first adjustable side wall;
the adjustable bracket further comprises a second adjustable side wall disposed parallel to and offset from the first adjustable side wall; and
the adjustable front wall is disposed between and connects the first adjustable side wall and the second adjustable side wall.

13. The system of claim 10, wherein:
the expansion card further comprises:
a proximal side including the edge connector;
a distal side opposite the proximal side;
a rear side supported by a rear portion of the fixed bracket; and
a front side opposite the rear side, wherein a distal-front corner comprises a portion of the card adjacent an intersection of the front side and the distal side of the card; and
the adjustable side portion supports the expansion card at the distal-front corner of the expansion card.

14. The system of claim 10, wherein the adjustable bracket is movable between multiple configurations by movement of the adjustable side portion and the adjustable front portion relative to the fixed bracket.

15. The system of claim 14, wherein:
the multiple configurations include a first configuration, a second configuration, and a third configuration;
in the first configuration, the adjustable front portion and the adjustable side portion is positioned at a first position;
in the second configuration the adjustable front portion is positioned at a second position rearward of the first position and the adjustable side portion is positioned at the first position; and
in the third position, the adjustable front portion is positioned at the second position and the adjustable side portion is positioned at a second position.

16. The system of claim 10, wherein:
the fixed top portion includes an opening to engage the adjustable side portion; and
movement of the adjustable side portion in a first direction comprises moving the adjustable side portion along the opening of the fixed top portion.

17. The system of claim 10, wherein:
the adjustable front portion includes an opening to engage the adjustable side portion; and
movement of the adjustable side portion in a second direction comprises moving the adjustable side portion along the opening of the adjustable front portion.

18. A method for installing an expansion card in a riser cage, comprising:
moving a first adjustable side portion, a second adjustable side portion, and an adjustable front portion in a first direction relative to a fixed bracket, the fixed bracket comprising a fixed top portion, a fixed side portion, and a fixed rear portion;
moving the second adjustable side portion in a second direction relative to the fixed bracket, wherein the second direction is perpendicular to the first direction;
fixing the first adjustable side portion and the second adjustable side portion; and
inserting an expansion card into a riser card expansion slot, wherein:
the expansion card is bounded by the first adjustable side portion, the second adjustable side portion, and the adjustable front portion; and
a corner of the expansion card is supported by the second adjustable side portion.

19. The method of claim 18, wherein fixing the first adjustable side portion and the second adjustable side portion further comprise engaging the first adjustable side portion and the second adjustable side portion with attachment points disposed on the fixed top portion of the fixed bracket.

20. The method of claim 18, wherein fixing the first adjustable side portion and the second adjustable side portion further comprise engaging the second adjustable side portion with attachment points disposed on the adjustable front portion.
